(19) United States
(12) Patent Application Publication
(10) Pub. No.: US 2019/0132997 A1
(43) Pub. Date: May 2, 2019

(54) WORKING SUBSTANCE CONTACTED COOLING SYSTEM FOR COMPUTER AND DATA CENTER

(71) Applicant: GUANGDONG HI-1 NEW MATERIALS TECHNOLOGY RESEARCH INSTITUTE CO., LTD., Guangzhou, Guangdong (CN)

(72) Inventor: Wei Wang, Guangzhou, Guangdong (CN)

(21) Appl. No.: 16/307,182

(22) PCT Filed: Oct. 14, 2016
(86) PCT No.: PCT/CN2016/102109

§ 371 Date: Dec. 5, 2018

(30) Foreign Application Priority Data
Jun. 16, 2016 (CN) 201610445639.X
Jun. 16, 2016 (CN) 201620608893.2

(51) Int. Cl. H05K 7/20

(52) U.S. Cl. CPC H05K 7/20781; H05K 7/20745

(57) ABSTRACT

A working substance contacted cooling system for computer and data center is disclosed. The system includes a server cabinet; a liquid working substance box arranged at a bottom of the server cabinet; a plurality of parallel and horizontally arranged partition plates with holes or grooves, on which server components are mounted; a main conduit dispenser vertically arranged, and communicated with the liquid working substance box through a main conduit; and a plurality of liquid working substance spraying pipes, a plurality of spray orifices being uniformly arranged on each said liquid working substance spraying pipe, each said liquid working substance spraying pipe being horizontally arranged above the server components for each layer and communicated with the main conduit dispenser; spraying directions of the spray orifices being corresponding to positions of server components; liquid working substance sprayed on the server components flowing back into the liquid working substance box.

### FIELD OF THE INVENTION

The present invention relates to Computer and Data Center cooling field, in particular to a working substance contacted cooling system for computer and data center.

### BACKGROUND OF THE INVENTION

With the rapid development of communication technology and electronics industry, high-density server deployment becomes an inevitable trend in the development of data centers, and efficient computers for various applications are also emerging. Smaller, more integrated and more high power density are developed in core compute components such as server components, processors, memory, etc. While the components possess high power performance, the heat dissipation problem is more obvious than before. If the heat dissipation problem cannot be effectively solved, it will inevitably limit the development depth of the high-performance data center. In the current technical field, the traditional air conditioning refrigeration mode is still applied in the data center. The air conditioning system is running all year round to provide an ambient temperature suitable for the normal operation of the data center; the air conditioning refrigeration COP has its limit value, and as the thermal load of the data center increases, the power consumption relative to the air conditioning system is large, and there also exits noise pollution. Moreover, in the data center of a high-density server, due to the excessive heat generated by a single cabinet or a small scale of several cabinets and the unreasonable airflow, it may lead to high local heat phenomena that cannot be solved by the air conditioning system. In the single computer cooling technology, in addition to the traditional forced air cooling technology, the mature application of heat pipe technology can help solve the heating problem of high power core computer components, but there still exits technical blind spots, and technical adaptability, structural life and other issues are still to be further verified.

### BRIEF SUMMARY OF THE INVENTION

The object of the present invention is to provide a working substance contacted cooling system for computer and data center, so that the problem in the prior art that high local heat phenomena that cannot be solved by the air conditioning system caused by the excessive heat generated by a single cabinet or a small scale of several cabinets and the unreasonable airflow leads to overhigh junction temperature of the electronic device, thus worsening the performance or causing failure of the device.

The solving solution for the above problem according to the present invention is as below:

a working substance contacted cooling system for computer and data center comprises:

a server cabinet;

a liquid working substance box arranged at a bottom of the server cabinet;

a plurality of parallelly and horizontally arranged partition plates with holes or grooves, on which server components are mounted;

a main conduit dispenser vertically arranged, which is in communication with the liquid working substance box through a main conduit; and

a plurality of liquid working substance spraying pipes, a plurality of spray orifices being uniformly arranged on each said liquid working substance spraying pipe, each said liquid working substance spraying pipe being horizontally arranged above the server components for each layer and being in communication with the main conduit dispenser; spraying directions of the spray orifices being corresponding to positions of the server components; liquid working substance from the liquid working substance box sprayed on the server components flowing back into the liquid working substance box.

The liquid working substance spraying pipes are horizontally arranged above the server components for each layer and the spraying liquid fully covers the server components, and the server components are cooled by spraying operation of the system, so as to improve the cooling efficiency.

Preferably, the spray orifices are connected with spraying nozzles; liquid sprayed by the spraying nozzles fully covers the server components.

The invention has the beneficial effects that the low-temperature, insulated and heat-conducting liquid working substance in the liquid working substance box is directly sprayed onto the server components through the spray orifices, and the sprayed fog liquid heat-conducting working substance directly contacts with the surface of the components, absorbs the heat generated by the components, and then falls back into the liquid working substance box. In this cycle, the liquid working substance ceaselessly transfers heat of the electronic device, and the cooling liquid working substance directly contacts the server components that need heat dissipation and no phase change occurs in the process of heat transferring, and there isn't any intermediate medium and heat transfer conversion. Significant advantages are listed in the following:

1. The sprayed liquid working substance forms an atomizing liquid film on the surface of heat generating device, and heat conduction of the liquid film has excellent heat transferring characteristics such as small flow, large temperature difference, high heat transfer coefficient and high heat flux density.

The spraying component for spraying liquid working substance has the advantages of simple structure, low power consumption, mature manufacturing technology and high reliability.

3. The liquid working substance can directly contact the surface of the single heat generating device, and improve the heat conduction efficiency by reducing the contact thermal resistance and reducing the indirect heat transfer structure. At the same time, the simpler the heat transferring process and structure, the higher the reliability and controllability.

4. Under the same ambient temperature, the temperature difference of direct contact cooling is controllable. Compared with the non-direct contact heat transfer method, the temperature of the heating surface of the device can be lowered and the junction temperature can be lowered, which helps to improve the working life and reliability of the server components.

5. Through adopting spraying for heat dissipation, the effective contact area (heat exchange area) between the liquid working substance and the heating surface will increase, so that the theoretical heat transfer efficiency will increase (the heat exchange amount is proportional to the area), and the effective utilization ratio of the liquid working substance is higher.

6. The heat transfer performance of liquid working fluid is generally better than the forced air convection, and compared with the traditional forced convection air cooling system that requires fresh air unit and some complicated structural design, the liquid cooling technology according to the present invention needs more simple design, and the spraying structure for direct contact is more simple, saving costs and extending device working life.

Based on the above technical solutions, the present invention can be improved as follows:

The present invention provides a working substance contacted cooling system for computer and data center as described above, and further, a top of the liquid working substance box is opened, a side wall of lower part of the server cabinet extends to form a side wall of the liquid working substance box, so that the side wall of the liquid working substance box and the side wall of the lower part of the server cabinet are formed in one piece; or, the liquid working substance box comprises a first liquid working substance box and a second liquid working substance box, a top of the first liquid working substance box is opened, a side wall of lower part of the server cabinet extends to form a side wall of the first liquid working substance box and the side wall of the first liquid working substance box and the side wall of the lower part of the server cabinet are formed in one piece, and the second liquid working substance box arranged outside the server cabinet is in communication with the first liquid working substance box.

The beneficial effects of the above further limitation are as follows: In the open cycle, non-phase-change liquid working substance is sprayed on the heating surface, the heat exchange area of the liquid working substance and the heating surface will increase, so that the theoretical heat transfer efficiency will be improved, the effective utilization ratio of the liquid working substance is higher, and the cooling efficiency is improved.

The present invention provides a working substance contacted cooling system for computer and data center as described above, and further, the system further comprises a liquid working substance pump arranged in or outside the liquid working substance box and the liquid working substance pump is in communication with the main conduit dispenser.

The present invention provides a working substance contacted cooling system for computer and data center as described above, and further, the system further comprises a filter installed at a front end of a liquid inlet of the liquid working substance pump.

The beneficial effects of the above further limitation are as follows: The filter is arranged at the front end of the liquid working fluid substance pump, and is used for filtering the liquid working substance for heat transferring in repeated circulation to ensure purity of the liquid working substance, thereby preventing damage to the pump body and clogging of the nozzle caused by impurities, and during the spraying process, there is no phase change occurring in the liquid working substance, so the system recycling does not require the working substance recovery equipment, and only the general filter is used to filter the impurities generated by the working substance in the open cycle, and the system adaptability and reliability are higher.

The present invention provides a working substance contacted cooling system for computer and data center as described above, and further, the system further comprises a liquid working substance cooling device to cool the liquid working substance in the liquid working substance box.

The beneficial effects of the above further limitation are as follows: the working substance in the liquid working substance box is cooled continuously, so as to ensure an effective temperature difference for heat exchange (usually 5 to 10° C.) between the liquid working substance and the server components for effective cooling.

The present invention provides a working substance contacted cooling system for computer and data center as described above, and further, the liquid working substance cooling device comprises a water chiller; the water chiller comprising a refrigerant compressor, a refrigerant conveying tube, a refrigerant returning tube and an evaporator; an outlet of the refrigerant compressor being in communication with one end of the evaporator through the refrigerant conveying tube, and an inlet of the refrigerant compressor being in communication with the other end of the evaporator through the refrigerant returning tube; the evaporator being arranged in the liquid working substance box.

The present invention provides a working substance contacted cooling system for computer and data center as described above, and further, the liquid working substance cooling device is a radiating fin installed outside the liquid working substance box.

The present invention provides a working substance contacted cooling system for computer and data center as described above, and further, the liquid working substance cooling device comprises a first heat exchange section outside the liquid working substance box and a second heat exchange section in the liquid working substance box; a refrigerant outlet of the first heat exchange section being in communication with a refrigerant inlet of the second heat exchange section, and a refrigerant outlet of the second heat exchange section being in communication with a refrigerant inlet of the first heat exchange section.

The present invention provides a working substance contacted cooling system for computer and data center as described above, and further, the system further comprises a blower used to cool the radiating fin or the first heat exchange section.

The present invention provides a working substance contacted cooling system for computer and data center as described above, and further, the liquid working substance is selected from the group consisting of natural mineral oil, silicone oil, vegetable oil, transformer oil, heat transfer oil and mixtures thereof.

The beneficial effects of the above further limitation are as follows: The above liquid working substance should be heat conducting liquid working substance with good insulation, to ensure the insulating performance of the working substance and avoid contact with the battery and then conducting electricity, resulting in battery damage and system scrapping. The liquid working substance generally has a high thermal conductivity, and can directly contact with the heat-generating battery in the spraying way, thereby realizing efficient heat dissipation of battery pack.

The server components of the present invention comprise a processor, a hard disk, a memory, a system bus, etc. The heat generated by the server components is mainly derived from CPU, GPU, memory and other components. By adopting the cooling medium, which is insulated liquid working substance for heat conducting, as non-polar material, to spray directly on the server components, the electronic, electrical equipment and circuit will not be affected and the hardware will not be damaged.

### BRIEF DESCRIPTION OF THE DRAWINGS

FIG. 1 is a main view of a working substance contacted cooling system for computer and data center according to one embodiment of the present invention;

FIG. 2 is a schematic diagram of a working substance contacted cooling system for computer and data center according to the first embodiment of the present invention;

FIG. 3 is a schematic diagram of a working substance contacted cooling system for computer and data center according to the second embodiment of the present invention;

FIG. 4 is a schematic diagram of a working substance contacted cooling system for computer and data center according to the third embodiment of the present invention;

FIG. 5 is a schematic diagram of a working substance contacted cooling system for computer and data center according to the fourth embodiment of the present invention;

### LIST OF REFERENCE NUMERALS

1. liquid working substance box
101. insulated liquid working substance
2. partition plates
3. server components
4. main conduit dispenser
5. main conduit
6. liquid working substance spraying pipes
7. spraying nozzles
8. liquid working substance pump
9. filter
10. refrigerant compressor
11. refrigerant conveying tube
12. refrigerant returning tube
13. evaporator
14. radiating fin
15. blower
16. the first heat exchange section
17. the second heat exchange section

### DETAILED DESCRIPTION OF ILLUSTRATED EMBODIMENTS

The principles and features of the present invention will be described in the following with reference to the drawings. The embodiments to be described are intended to be illustrative only and not to limit the scope of the present invention.

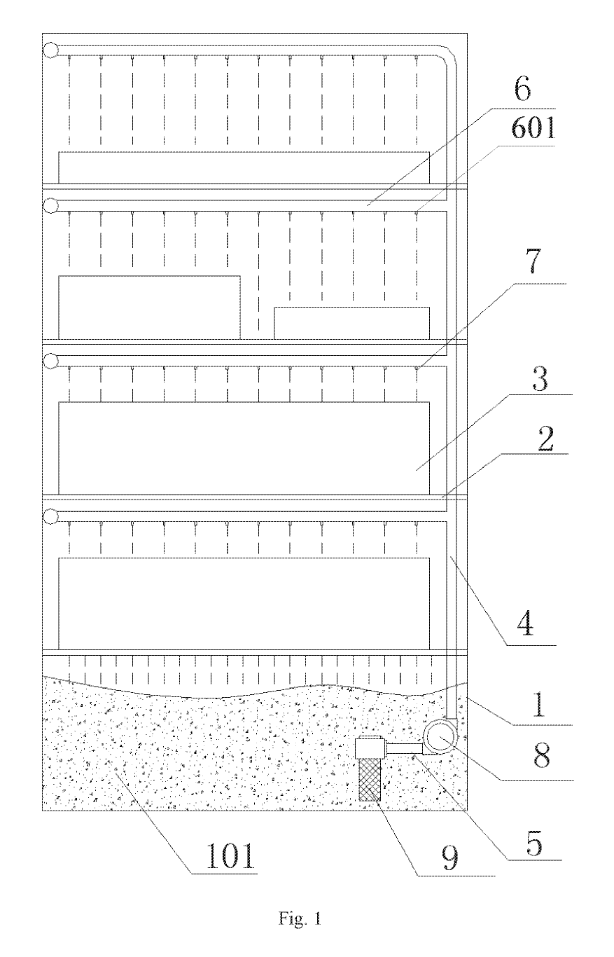

With reference to FIGS. 1-5, a working substance contacted cooling system for computer and data center comprises a server cabinet 301; a liquid working substance box 1, the liquid working substance box 1 arranged at a bottom of the server cabinet 301; a plurality of parallelly and horizontally arranged partition plates 2 with holes or grooves, on which server components 3 are mounted; a main conduit dispenser 4 vertically arranged, which is in communication with the liquid working substance box 1 through a main conduit 5; a plurality of liquid working substance spraying pipes 6, a plurality of spray orifices being uniformly arranged on each said liquid working substance spraying pipe, each said liquid working substance spraying pipe being horizontally arranged above the server components 3 for each layer and being in communication with the main conduit dispenser 4. That is, the liquid working spray pipes 6 are arranged in parallel above the server components 3 for each layer and the spraying liquid fully covers the server components 3. Spraying directions of the spray orifices are corresponding to positions of the server components 2; liquid working substance sprayed on the server components 3 flows back into the liquid working substance box 1. Specifically, the spray orifices are connected with spraying nozzles 7, which are directly facing the server components 3 and the liquid can be sprayed onto the server components 3 more accurately.

In the embodiment of the present invention, one end of the main conduit dispenser 4 is connected with the liquid working substance pump 8, and N (N≥1) three-way joints are arranged at different heights, on which liquid working substance spraying pipes 6 for the same heights are mounted. Each said liquid working substance spraying pipe is provided with a plurality of spraying nozzles 7; each said spraying nozzle sprays towards the components that need heat dissipation. The spraying nozzles should be made of materials with good insulation and engineering strength; According to one embodiment of the present invention, the low-temperature, insulated and heat-conducting liquid working substance in the liquid working substance box 1 is directly sprayed onto the server components 3 through the spray orifices, and the sprayed fog liquid heat-conducting working substance directly contacts with the surface of the components, absorbs the heat generated by the components, and then falls back into the liquid working substance box 1. In this cycle, the liquid working substance ceaselessly transfers heat of the electronic device, and the cooling liquid working substance directly contacts the server component that need heat dissipation and no phase change exists in the process of heat transferring, as well as any intermediate medium and heat transfer conversion. The spraying structure can be simpler, thus saving cost, extending device working life and improving the cooling effect.

According to a working substance contacted cooling system for computer and data center in one embodiment of the present invention, a top of the liquid working substance box 1 is opened, a side wall of lower part of the server cabinet 301 extends to form a side wall of the liquid working substance box 1, so that the side wall of the liquid working substance box 1 and the side wall of the lower part of the server cabinet 301 are formed in one piece; or, the liquid working substance box 1 comprises a first liquid working substance box and a second liquid working substance box, a top of the first liquid working substance box is opened, a side wall of lower part of the server cabinet 301 extends to form a side wall of the first liquid working substance box and the side wall of the first liquid working substance box, so that the side wall of the lower part of the server cabinet 301 are formed in one piece, and the second liquid working substance box arranged outside the server cabinet 301 is in communication with the first liquid working substance box 1. According to the above structure, a liquid working substance box 1 can be formed by directly taking advantage of the original space of the server cabinet 301, and the liquid sprayed on the server components 3 from a plurality of liquid working substance spraying pipes 6 directly flows back into the liquid working substance box 1 formed by the lower part of the cabinet. The system framework is simple, and the heat exchange area of the liquid working substance and the heating surface will increase, so that the theoretical heat transfer efficiency will be improved, the effective utilization ratio of the liquid working substance is higher, and the cooling efficiency is improved.

In the above embodiments, specifically, the main conduit dispenser 4 is vertically arranged, a plurality of liquid working substance spraying pipes 6 are uniformly arranged on the main conduit dispenser 4, one end of each liquid working substance spraying pipe is communicated with the main conduit dispenser 4, the other end of each liquid working substance spraying pipe is blocked.

In one preferred embodiment of the present invention, the system further comprises a liquid working substance pump 8, the liquid working substance pump 8 is arranged in the liquid working substance box 1 and communicated with the main conduit dispenser 4; specifically, the system further comprises a filter 9, which is installed at a front end of a liquid inlet of the liquid working substance pump 8. By arranging the liquid working substance pump 8 and the filter 9, it will ensure circulation performance and purity of the liquid working substance, thus preventing damage to the pump body and clogging of the nozzle caused by impurities. The system adaptability and reliability are higher.

In the above embodiments, a plurality of liquid working substance spraying pipes 6 may also be vertically arranged on three sides of the server components 3. The liquid can be sprayed towards three sides of the server components 3 to improve the cooling efficiency.

In preferred embodiments of the present invention, specifically, the system comprises a liquid working substance cooling device, which is used to cool liquid working substance in the liquid working substance box 1. The working substance in the liquid working substance box 1 is cooled continuously, so as to ensure an effective temperature difference for heat exchange (usually 5 to 10° C.) between the liquid working substance and the server components 3 for effective cooling.

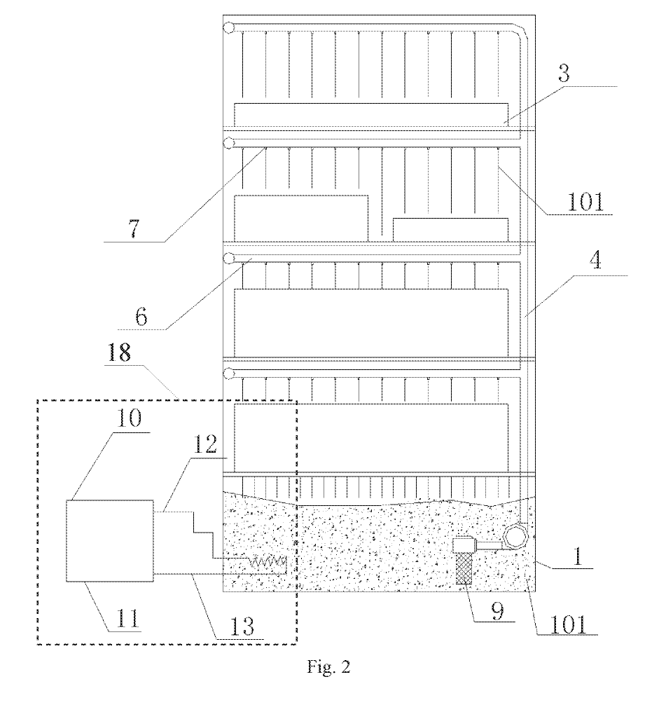

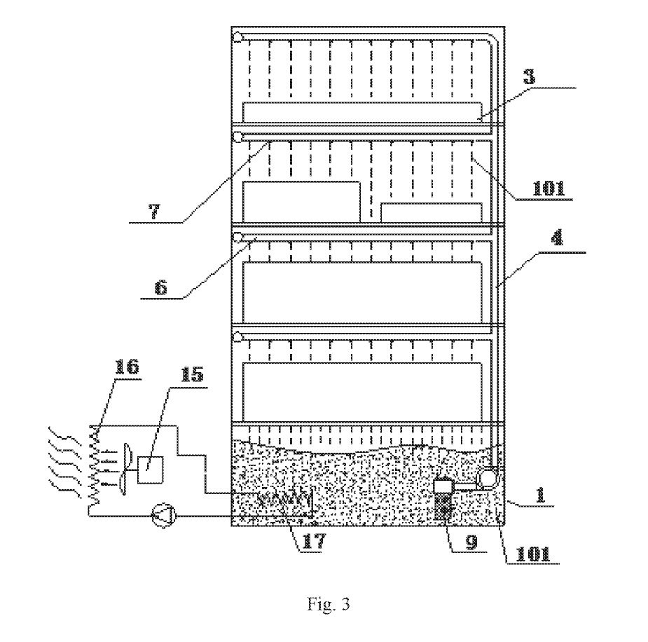

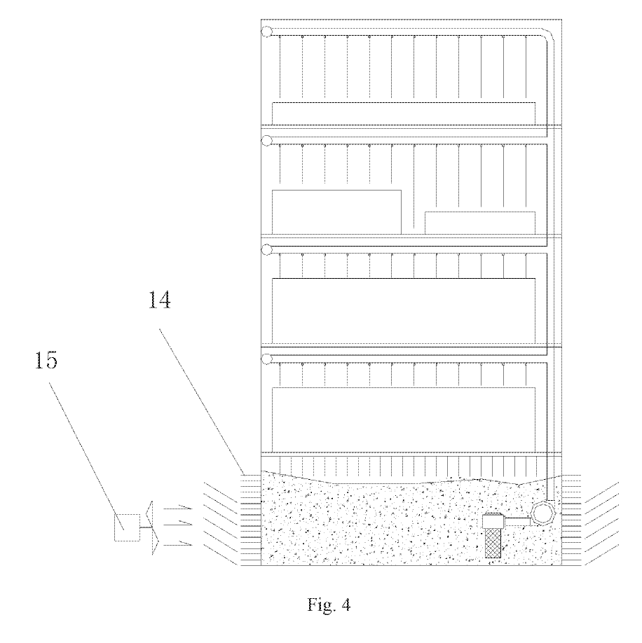

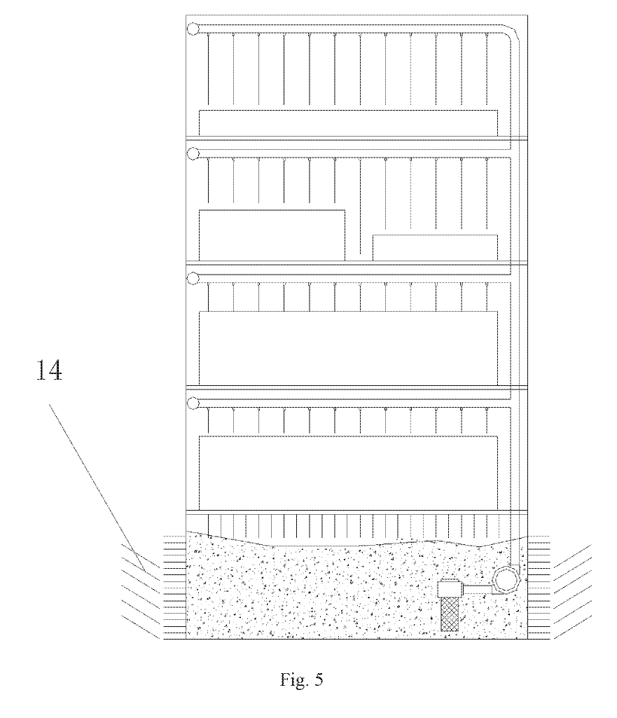

The above liquid working fluid cooling device can be realized in the following manners: Firstly, with reference to FIG. 2, the liquid working substance cooling device comprises a water chiller; the water chiller comprises a refrigerant compressor 10, a refrigerant conveying tube 11, a refrigerant returning tube 12 and an evaporator 13; an outlet of the refrigerant compressor 10 is in communication with one end of the evaporator 13 through the refrigerant conveying tube 11, and an inlet of the refrigerant compressor 10 is in communication with other end of the evaporator 13 through the refrigerant returning tube 12; the evaporator 13 is arranged in the liquid working substance box 1. Secondly, with reference to FIG. 5, the liquid working substance cooling device is a radiating fin 14 installed outside the liquid working substance box 1. Thirdly, with reference to the FIG. 4, with reference to FIG. 4, a blower 15 is disposed outside a radiating fin 14 outside the liquid working substance box 1 taken as the liquid working substance cooling device; the blower is used to cool down the radiating fin 14. Fourthly, the liquid working substance cooling device comprises a first heat exchange section 16 arranged outside the liquid working substance box 1 and a second heat exchange section 17 arranged in the liquid working substance box 1; a refrigerant outlet of the first heat exchange section 16 is in communication with a refrigerant inlet of the second heat exchange section 17 through a tube, and a refrigerant outlet of the second heat exchange section 17 is in communication with a refrigerant inlet of the first heat exchange section 16 through a tube, a refrigerant of the circulation loop of the first heat exchange section and the second heat exchange section may be water or air. Fifthly, with reference to FIG. 3, the liquid working substance cooling device comprises a first heat exchange section 16 arranged outside the liquid working substance box 1 and a second heat exchange section 17 arranged in the liquid working substance box 1; a refrigerant outlet of the first heat exchange section 16 is in communication with a refrigerant inlet of the second heat exchange section 17 through a tube, and a refrigerant outlet of the second heat exchange section 17 is in communication with a refrigerant inlet of the first heat exchange section 16 through a tube, a refrigerant of the circulation loop of the first heat exchange section and the second heat exchange section may be water or air; a blower 15 is disposed outside the first heat exchange section 16 for cooling down the first heat exchange section 16.

In one preferred embodiment of the present invention, the insulated liquid working substance 2 is selected from the group consisting of natural mineral oil, silicone oil, vegetable oil, transformer oil, heat transfer oil and mixtures thereof. The above liquid working substance should be heat conducting liquid working substance with good insulation, to ensure the insulating performance of the working substance and avoid contact with the server components and then conducting electricity, resulting in electronic devices damage and system scrapping. The liquid working substance generally has a high thermal conductivity, and can directly contact with the heat-generating electronic devices in the spraying way, thereby realizing efficient heat dissipation of server

The server components 3 of the present invention comprise a processor, a hard disk, a memory, a system bus, etc. The heat generated by the server components 3 is mainly derived from CPU, GPU, memory and other components. By adopting the cooling medium, which is insulated liquid heat conducting working substance, as non-polar material, to spray directly on the server components 3, the electronic, electrical equipment and circuit will not be affected and the hardware will not be damaged.

The above are only preferred embodiments of the present invention and are not intended to limit the scope thereof. Any modification, equivalent substitution, improvement, etc. made within the spirit and principles of the present invention shall be included in the protection scope of the present invention.

1. A working substance contacted cooling system for computer and data center, wherein the system comprises:
a server cabinet;
a liquid working substance box arranged at a bottom of the server cabinet;
a plurality of parallelly and horizontally arranged partition plates with holes or grooves, on which server components are mounted;
a main conduit dispenser vertically arranged, which is in communication with the liquid working substance box through a main conduit; and
a plurality of liquid working substance spraying pipes, a plurality of spray orifices being uniformly arranged on each said liquid working substance spraying pipe, each said liquid working substance spraying pipe being horizontally arranged above the server components for each layer and being in communication with the main conduit dispenser; spraying directions of the spray orifices being corresponding to positions of the server components; liquid working substance from the liquid working substance box sprayed on the server components flowing back into the liquid working substance box.

2. The working substance contacted cooling system for computer and data center according to claim 1, wherein a top of the liquid working substance box is opened, a side wall of a lower part of the server cabinet extends to form a side wall of the liquid working substance box, so that the side wall of the liquid working substance box and the side wall of the lower part of the server cabinet are formed in one piece; or, the liquid working substance box comprises a first liquid working substance box and a second liquid working substance box, a top of the first liquid working substance box is opened, a side wall of a lower part of the server cabinet extends to form a side wall of the first liquid working substance box, so that the side wall of the first liquid working substance box and the side wall of the lower part of the server cabinet are formed in one piece, and the second liquid working substance box arranged outside the server cabinet is in communication with the first liquid working substance box.

3. The working substance contacted cooling system for computer and data center according to claim 1, wherein the system further comprises a liquid working substance pump arranged in or outside the liquid working substance box and the liquid working substance pump is in communication with the main conduit dispenser.

4. The working substance contacted cooling system for computer and data center according to claim 3, wherein the system further comprises a filter installed at a front end of a liquid inlet of the liquid working substance pump.

5. The working substance contacted cooling system for computer and data center according to claim 1, wherein the system further comprises a liquid working substance cooling device to cool the liquid working substance in the liquid working substance box.

6. The working substance contacted cooling system for computer and data center according to claim 5, wherein the liquid working substance cooling device comprises a water chiller; the water chiller comprising a refrigerant compressor, a refrigerant conveying tube, a refrigerant returning tube and an evaporator; an outlet of the refrigerant compressor being in communication with one end of the evaporator through the refrigerant conveying tube, and an inlet of the refrigerant compressor being in communication with the other end of the evaporator through the refrigerant returning tube; the evaporator being arranged in the liquid working substance box.

7. The working substance contacted cooling system for computer and data center according to claim 5, wherein the liquid working substance cooling device is a radiating fin installed outside the liquid working substance box.

8. The working substance contacted cooling system for computer and data center according to claim 5, wherein the liquid working substance cooling device comprises a first heat exchange section arranged outside the liquid working substance box and a second heat exchange section arranged in the liquid working substance box; a refrigerant outlet of the first heat exchange section being in communication with a refrigerant inlet of the second heat exchange section, and a refrigerant outlet of the second heat exchange section being in communication with a refrigerant inlet of the first heat exchange section.

9. The working substance contacted cooling system for computer and data center according to claim 7, wherein the system further comprises a blower to cool the radiating fin.

10. The working substance contacted cooling system for computer and data center according to claim 1, wherein the liquid working substance is selected from the group consisting of natural mineral oil, silicone oil, vegetable oil, transformer oil, heat transfer oil and mixtures thereof.

11. The working substance contacted cooling system for computer and data center according to claim 2, wherein the system further comprises a liquid working substance pump arranged in or outside the liquid working substance box and the liquid working substance pump is in communication with the main conduit dispenser.

12. The working substance contacted cooling system for computer and data center according to claim 11, wherein the system further comprises a filter installed at a front end of a liquid inlet of the liquid working substance pump.

13. The working substance contacted cooling system for computer and data center according to claim 2, wherein the system further comprises a liquid working substance cooling device to cool the liquid working substance in the liquid working substance box.

14. The working substance contacted cooling system for computer and data center according to claim 13, wherein the liquid working substance cooling device comprises a water chiller; the water chiller comprising a refrigerant compressor, a refrigerant conveying tube, a refrigerant returning tube and an evaporator; an outlet of the refrigerant compressor being in communication with one end of the evaporator through the refrigerant conveying tube, and an inlet of the refrigerant compressor being in communication with the other end of the evaporator through the refrigerant returning tube; the evaporator being arranged in the liquid working substance box.

15. The working substance contacted cooling system for computer and data center according to claim 13, wherein the liquid working substance cooling device is a radiating fin installed outside the liquid working substance box.

16. The working substance contacted cooling system for computer and data center according to claim 13, wherein the liquid working substance cooling device comprises a first heat exchange section arranged outside the liquid working substance box and a second heat exchange section arranged in the liquid working substance box; a refrigerant outlet of the first heat exchange section being in communication with a refrigerant inlet of the second heat exchange section, and a refrigerant outlet of the second heat exchange section being in communication with a refrigerant inlet of the first heat exchange section.

17. The working substance contacted cooling system for computer and data center according to claim 8, wherein the system further comprises a blower to cool the first heat exchange section.

18. The working substance contacted cooling system for computer and data center according to claim 15, wherein the system further comprises a blower to cool the radiating fin.

19. The working substance contacted cooling system for computer and data center according to claim 16, wherein the system further comprises a blower to cool the first heat exchange section.

20. The working substance contacted cooling system for computer and data center according to claim 2, wherein the liquid working substance is selected from the group consisting of natural mineral oil, silicone oil, vegetable oil, transformer oil, heat transfer oil and mixtures thereof.
